(19) United States
(12) Patent Application Publication
(10) Pub. No.: US 2025/0248024 A1
(43) Pub. Date: Jul. 31, 2025

(54) SEMICONDUCTOR DEVICES AND FABRICATING METHODS THEREOF

(71) Applicant: YANGTZE MEMORY TECHNOLOGIES CO., LTD., Wuhan (CN)

(72) Inventors: Wei Xu, Wuhan (CN); Zongliang Huo, Wuhan (CN); Jiajia Wu, Wuhan (CN); Beibei Li, Wuhan (CN)

(21) Appl. No.: 18/435,751

(22) Filed: Feb. 7, 2024

Related U.S. Application Data
(63) Continuation of application No. PCT/CN2024/073991, filed on Jan. 25, 2024.

(51) Int. Cl. H10B 12/00; H01L 23/522; H01L 23/528; H01L 23/532

(52) U.S. Cl. CPC H10B 12/315; H01L 23/5226; H01L 23/5283; H01L 23/53257; H01L 23/5329; H10B 12/0335; H10B 12/05

(57) ABSTRACT

Memory devices and fabricating methods thereof are disclosed. In some implementations, the disclose memory device comprises a capacitor stack structure and an array of transistors. The capacitor stack structure comprises first electrode plates and second electrode plates alternatively stacked along a vertical direction, a common electrode vertically extending through the capacitor stack structure and in contact with the first electrode plates, and select electrodes each extending through the capacitor stack structure and in contact with a corresponding one of the second electrode plates. Each transistor of the array of transistors is coupled with a corresponding one of the select electrodes.

### CROSS-REFERENCE TO RELATED APPLICATIONS

This application is a continuation of International Application No. PCT/CN2024/073991, filed on Jan. 25, 2024, entitled “SEMICONDUCTOR DEVICES AND FABRICATING METHODS THEREOF,” which is incorporated herein by reference in its entirety.

### TECHNICAL FIELD

The present disclosure generally relates to the field of semiconductor technology, and more particularly, to semiconductor devices and fabricating methods thereof.

### BACKGROUND

Planar memory cells are scaled to smaller sizes by improving process technology, circuit design, programming algorithm, and fabrication process. However, as feature sizes of the memory cells approach a lower limit, planar process, and fabrication techniques become challenging and costly. As a result, memory density for planar memory cells approaches an upper limit.

A three-dimensional (3D) memory architecture can address the density limitation in planar memory cells. The 3D memory architecture includes a memory array and peripheral circuits for facilitating operations of the memory array.

### SUMMARY

One aspect of the present disclosure provides a semiconductor device, comprising: a stack structure comprising first conductive layers and second conductive layers alternately stacked along a vertical direction; a conductive wall vertically extending through the stack structure and in contact with the first conductive layers but isolated from the second conductive layers; and conductive vias each vertically extending through the stack structure and electrically connected with a corresponding one of the second conductive layers but electrically isolated from the first conductive layers and other second conductive layers in the stack structure.

In some implementations, the semiconductor device further comprises: isolation structures between the conductive vias and the other second conductive layers to isolated the conductive vias and the other second conductive layers.

In some implementations, the semiconductor device further comprises: conductive connection structures each between one of the conductive vias and the corresponding one of the second conductive layers to connect the one of the conductive vias to the corresponding one of the second conductive layers.

In some implementations, the isolation structures comprise silicon oxide; and the conductive connection structures comprise a metal silicide material.

In some implementations, each of the isolation structures and the conductive connection structures has a ring structure laterally surrounding a corresponding one of the conductive vias.

In some implementations, the second conductive layers and the first conductive layers comprise a same conductive material.

In some implementations, the first conductive layers and the conductive wall comprise a first conductive material; and the second conductive layers and the conductive vias comprise a second conductive material different from the first conductive material.

In some implementations, the semiconductor device further comprises: a dielectric layer comprising: horizontal portions between adjacent first conductive layers and second conductive layers; first vertical portions between the conductive wall and the second conductive layers; and second vertical portions between the conductive vias and the first conductive layers.

In some implementations, the dielectric layer comprises a high-K material.

In some implementations, the dielectric layer is in contact with side surfaces of the conductive wall and the conductive vias, and horizontal surfaces of the first conductive layers and second conductive layers.

In some implementations, the semiconductor device further comprises: an array of transistors coupled with the conductive vias, respectively.

In some implementations, the transistors are vertical gate transistors each comprising a channel structure extending along a vertical direction and a gate structure at a lateral side of the channel structure.

In some implementations, the semiconductor device further comprises: an insulating layer between the stack structure and the array of transistors, wherein each conductive via extends through the insulating layer to couple with a corresponding one of the array of transistors.

In some implementations, a first thickness of the first conductive layers is different from a second thickness of the second conductive layers.

In some implementations, the semiconductor device further comprises: a slit structure extending vertically through the stack structure and laterally along a first direction between adjacent rows of conductive vias, wherein the conductive wall extends laterally along a second direction to cut off the slit structure.

Another aspect of the present disclosure provides a memory device, comprising: a capacitor stack structure comprising: first electrode plates and second electrode plates alternatively stacked along a vertical direction, a common electrode vertically extending through the capacitor stack structure and in contact with the first electrode plates, and select electrodes each extending through the capacitor stack structure and in contact with a corresponding one of the second electrode plates; and an array of transistors each coupled with a corresponding one of the select electrodes.

In some implementations, the memory device further comprises: a high-K layer between adjacent first electrode plates and second electrode plates, between the first electrode plates and the common electrode, and between the second electrode plates and the select electrodes.

In some implementations, the memory device further comprises: conductive connection structures each between one of the select electrodes and the corresponding one of the second electrode plates to electrically connect the one of the select electrodes and the corresponding one of the second electrode plates; and isolation structures between the one of the select electrodes and other second electrode plates different from the corresponding one of the second electrode plates.

In some implementations, the isolation structures comprise silicon oxide, the conductive connection structures comprise a metal silicide material.

In some implementations, each of the isolation structures and the conductive connection structures has a ring structure laterally surrounding a corresponding one of the select electrodes.

In some implementations, the first electrode plates and the second electrode plates comprise a same conductive material.

In some implementations, the first electrode plates and the common electrode comprise a first conductive material; and the second electrode plates and the select electrodes comprise a second conductive material different from the first conductive material.

In some implementations, the memory device further comprises: an insulating layer between the capacitor stack structure and the array of transistors, wherein the select electrodes extend through the insulating layer.

In some implementations, the transistors are two-dimensional transistors or vertical gate transistors.

In some implementations, the memory device further comprises: a slit structure extending vertically through the capacitor stack structure and laterally along a first direction between adjacent rows of select electrodes, wherein the common electrode extends laterally along a second direction to cut off the slit structure.

Another aspect of the present disclosure provides a method for forming a semiconductor device, comprising: forming a stack structure on an array of transistors, the stack structure comprising semiconductor layers and sacrificial layers alternately stacked along a vertical direction; forming through holes each vertically extending through the stack structure, and forming isolation structures and conductive connection structures in the through holes on exposed sidewalls of the semiconductor layers, such that each through hole has one conductive connection structure in contact with a corresponding one of the semiconductor layers, and the sidewalls of other semiconductor layers being covered by the isolation structures; forming conductive vias in the through holes to connect the array of transistors; replacing the semiconductor layers with second conductive layers; and replacing the sacrificial layers with first conductive layers.

In some implementations, the method further comprises: forming an insulating layer on the array of transistors, wherein the stack structure is formed on the insulating layer.

In some implementations, forming the through holes, the isolation structures, and the conductive connection structures comprises: forming via holes having different depths in the stack structure, each via hole stops at a corresponding one of the sacrificial layers; and oxidizing exposed surfaces of the semiconductor layers through the via holes to form isolation structures.

In some implementations, forming the through holes, the isolation structures, and the conductive connection structures further comprises: first extending the depths of the via holes, such that each via hole exposes one lower semiconductor layer without the isolation structures; and forming conductive connection structures on exposed sidewalls of the semiconductor layers without the isolation structures through the first extended via holes.

In some implementations, forming the through holes, the isolation structures, and the conductive connection structures further comprises: second extending the depths of the via holes, such that each via hole stops at the insulating layer; and oxidizing exposed surfaces of the semiconductor layers through the second extended via holes to form additional isolation structures.

In some implementations, forming the through holes, the isolation structures, and the conductive connection structures further comprises: third extending the depths of the via holes to form the through holes, such that each through hole extends through the insulating layer and exposes a corresponding one of the transistors.

In some implementations, replacing the semiconductor layers with the second conductive layers comprises: forming a vertical trench vertically extending through the stack structure and stopping at the insulating layer; removing the semiconductor layers through the vertical trench to form first horizontal trenches; and forming the second conductive layers in the first horizontal trenches.

In some implementations, replacing the sacrificial layers with the first conductive layers comprises: removing portions of the second conductive layers exposed by the vertical trench; removing the sacrificial layers through the vertical trench to form second horizontal trenches; forming a dielectric layer in the second horizontal trenches and on sidewalls of the vertical trench to cover exposed surfaces of the second conductive layers; and forming the first conductive layers in the second horizontal trenches.

In some implementations, the method further comprises: forming slit structures extending vertically through the stack structure and laterally along a first direction, wherein a row of through holes are formed between adjacent first slit structures.

### BRIEF DESCRIPTION OF THE DRAWINGS

The accompanying drawings, which are incorporated herein and form a part of the specification, illustrate implementations of the present disclosure and, together with the description, further serve to explain the principles of the present disclosure and to enable a person skilled in the pertinent art to make and use the present disclosure.

FIG. 1 illustrates a schematic circuit diagram of a memory device including vertical transistors, according to some implementations of the present disclosure.

FIG. 2 illustrates a schematic side cross-sectional view of a 3D memory device, according to some implementations of the present disclosure.

FIG. 3 illustrates a schematic planar cross-sectional view of a memory device, according to some implementations of the present disclosure.

FIG. 4 illustrates a block diagram of a system having a memory device, according to some implementations of the present disclosure.

FIG. 5 illustrates a flowchart of a fabricating method for forming a 3D memory device, according to some implementations of the present disclosure.

FIG. 6A illustrates a schematic side cross-sectional view of a 3D memory device at a certain stage of a fabricating method, according to some implementations of the present disclosure.

FIG. 6B illustrates a schematic planar cross-sectional view of a 3D memory device at a certain stage of a fabricating method, according to some implementations of the present disclosure.

FIG. 7A illustrates a schematic side cross-sectional view of a 3D memory device at a certain stage of a fabricating method, according to some implementations of the present disclosure.

FIG. 7B illustrates a schematic planar cross-sectional view of a 3D memory device at a certain stage of a fabricating method, according to some implementations of the present disclosure.

FIG. 8A illustrates a schematic side cross-sectional view of a 3D memory device at a certain stage of a fabricating method, according to some implementations of the present disclosure.

FIG. 8B illustrates a schematic planar cross-sectional view of a 3D memory device at a certain stage of a fabricating method, according to some implementations of the present disclosure.

FIG. 9A illustrates a schematic side cross-sectional view of a 3D memory device at a certain stage of a fabricating method, according to some implementations of the present disclosure.

FIG. 9B illustrates a schematic planar cross-sectional view of a 3D memory device at a certain stage of a fabricating method, according to some implementations of the present disclosure.

FIG. 10 illustrates a schematic side cross-sectional view of a 3D memory device at a certain stage of a fabricating method, according to some implementations of the present disclosure.

FIG. 11 illustrates a schematic side cross-sectional view of a 3D memory device at a certain stage of a fabricating method, according to some implementations of the present disclosure.

FIG. 12A illustrates a schematic side cross-sectional view of a 3D memory device at a certain stage of a fabricating method, according to some implementations of the present disclosure.

FIG. 12B illustrates a schematic planar cross-sectional view of a 3D memory device at a certain stage of a fabricating method, according to some implementations of the present disclosure.

FIG. 13A illustrates a schematic side cross-sectional view of a 3D memory device at a certain stage of a fabricating method, according to some implementations of the present disclosure.

FIG. 13B illustrates a schematic planar cross-sectional view of a 3D memory device at a certain stage of a fabricating method, according to some implementations of the present disclosure.

FIG. 14 illustrates a schematic side cross-sectional view of a 3D memory device at a certain stage of a fabricating method, according to some implementations of the present disclosure.

FIG. 15A illustrates a schematic side cross-sectional view of a 3D memory device at a certain stage of a fabricating method, according to some implementations of the present disclosure.

FIG. 15B illustrates a schematic planar cross-sectional view of a 3D memory device at a certain stage of a fabricating method, according to some implementations of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

Transistors are used as the switch or selecting devices in the memory cells of some memory devices, such as dynamic radon access memory (DRAM). In a one-transistor-one-capacitor (1T1C) DRAM structure, the data are stored in the capacitors. The vertical transistors can have different gate structure architecture designs, such as single metal gate (SMG), double metal gate (DMG), triple metal gate (TMG), gate all around (GAA), etc. The vertical capacitors are generally formed by a drilling process to form vertical tubes that have limited aperture size. Due to the limitations of the drilling process, the existing fabricating process is difficult to increase the capacitance capacity, and the process window is very small.

To address one or more of the aforementioned issues, the present disclosure introduces a novel design of the architecture of the capacitors. The existing vertically placed tubular capacitors are changed into planar stacked-plates capacitors. Vertical conductive vias are used to connect the transistors and the capacitors. Poly oxidation is used to form isolation structures between the vertical conductive vias and the planar stacked plates. Further, a silicide structure (e.g., Ti/Co/Ni) can be used to select the capacitor plate layers that need to be connected to the vertical conductive vias, thereby avoiding using any recess process. As such, the challenges of shrinking of existing capacitors due to the limited aperture size by using the recess process, as well as the size requirement and uniformity requirement for the vertical holes, can be avoided to achieve the goal of selecting layers. Therefore, the disclosed capacitor stack structure can realize large capacitance and size shrinking to cooperate with the downsizing of the transistors.

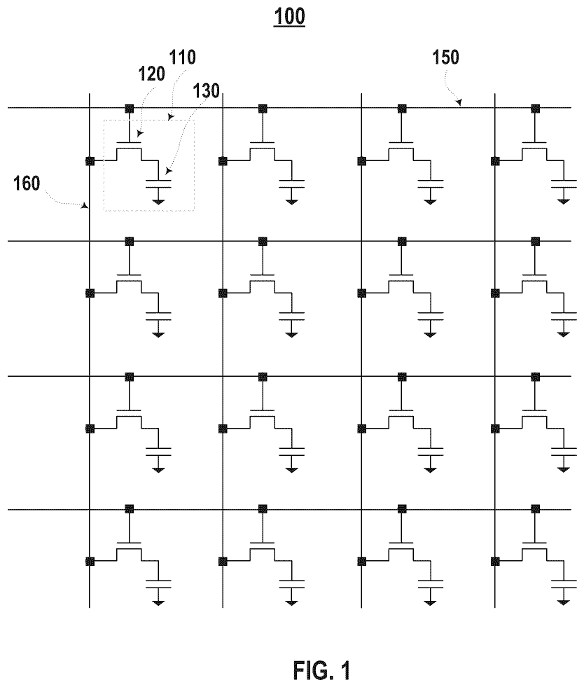

FIG. 1 illustrates a schematic diagram of a memory device 100 having an array of memory cells, each having a vertical transistor, according to some implementations of the present disclosure. Memory device 100 can include a memory cell array in which each memory cell 110 includes a vertical transistor 120 and a storage unit coupled to vertical transistor 120. In some implementations as shown in FIG. 1, the memory cell array is a DRAM cell array, and the storage unit is a capacitor 130 for storing charge as the binary information stored by the respective DRAM cell. In some other implementations not shown in the figures, the memory cell array is a PCM cell array, and the storage unit can be a PCM element (e.g., including chalcogenide alloys) for storing binary information of the respective PCM cell based on the different resistivities of the PCM element in the amorphous phase and the crystalline phase.

As shown in FIG. 1, memory cells 110 can be arranged in a two-dimensional (2D) array having rows and columns. Memory device 100 can include word lines 150 coupling the memory cell array to peripheral circuits for controlling the switch of vertical transistors 120 in memory cells 110 located in a row, as well as bit lines 160 coupling the memory cell array to peripheral circuits for sending data to and/or receiving data from memory cells 110 located in a column. That is, each word line 150 is coupled to a respective row of memory cells 110, and each bit line 160 is coupled to one or more respective logic columns of memory cells 110.

In some implementations of the present disclosure, the vertical transistors 120 can be vertical metal-oxide-semiconductor field-effect transistors (MOSFETs). The gate of vertical transistor 120 is coupled to word line 150, one of the source and the drain of vertical transistor 120 is coupled to bit line 160, the other one of the source and the drain of vertical transistor 120 is coupled to one electrode of capacitor 130, and the other electrode of capacitor 130 is coupled to the ground. In some implementations, the capacitors 130 can have a stack structure as described in detail below.

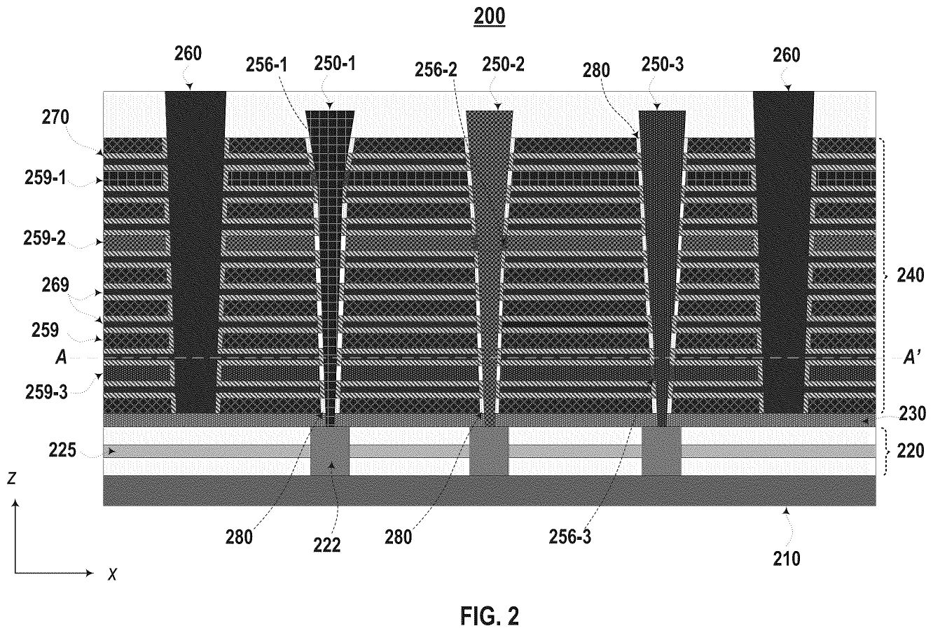

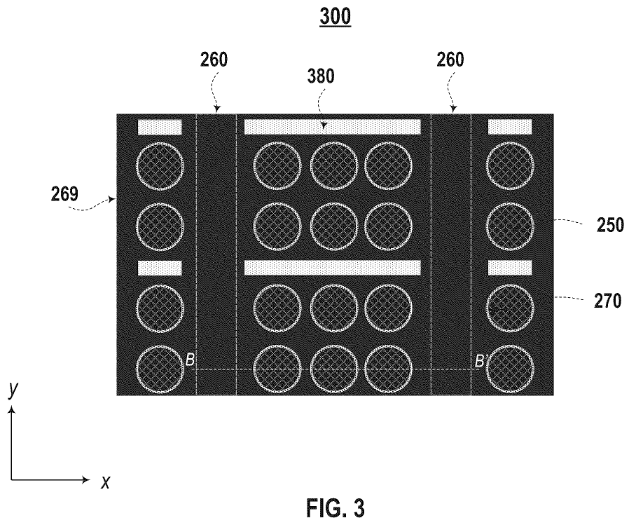

FIG. 2 illustrates a schematic side cross-sectional view of a 3D memory device, according to some implementations of the present disclosure. FIG. 3 illustrates a schematic planar cross-sectional view of a memory device, according to some implementations of the present disclosure. It is noted that, FIG. 3 illustrates the planar section 300 of the memory device shown in FIG. 2 along the A-A′ line, while FIG. 2 illustrates the cross-section 200 of the 3D memory device shown in FIG. 2 along the B-B′ line.

As shown in FIG. 2, the disclosed memory device can include a transistor layer 220 on a substrate 210. Substrate 210 can be a semiconductor substrate, which can include silicon (e.g., single crystalline silicon, c-Si), silicon germanium (SiGe), gallium arsenide (GaAs), germanium (Ge), silicon-on-insulator (SOI), or any other suitable materials. In some other implementations, the substrate 210 can be a carrier substrate, which can include any suitable semiconductor materials, or an electrically non-conductive material, such as a glass, a plastic, or a sapphire wafer.

The transistor layer 220 can include an array of vertical transistors, such as an array of gate-all-around (GAA) type vertical transistors, or single metal gate (SMG) type vertical transistors, double metal gate (DMG) type vertical transistors, triple metal gate (TMG) type vertical transistors, etc. Specifically, the transistor layer 220 can include array of channel structures 222, each extending along a vertical direction (as shown in FIGS. 2 and 3), and a gate structure layer 225 along a lateral direction. The gate structure layer 225 can include a plurality of gate structures each located at one or more sides of the corresponding channel structure 222. Each gate structure can include a gate electrode and a gate dielectric. In some implementations, the gate structures of a row of vertical transistors along a first lateral direction can form a word line. Thus, the first lateral direction (the x-direction) can also be referred to as the word line direction. Although not shown in FIG. 2, the disclosed memory device can further include a plurality of bit lines, each extending in a second lateral direction perpendicular to the first lateral direction (the y-direction, referred to as the bit line direction). Each bit line can connect to a corresponding column of vertical transistors along the second lateral direction (the y-direction).

As shown in FIG. 2, the disclosed memory device can further include a capacitor stack structure 240 comprising first conductive layers 269 (also referred to as first electrode plates 269) and second conductive layers 259 (also referred to as second electrode plates 259) alternately stacked along a vertical direction (the z-direction). In some implementations, a first thickness of the first conductive layers 269 is different from a second thickness of the second conductive layers 259. As shown in FIGS. 2 and 3, one or more conductive walls 260 (also referred to as common electrodes 260) can vertically extend through the capacitor stack structure 240 and in contact with the first conductive layers 269 but isolated from the second conductive layers 259. A plurality of conductive vias 250 (also referred to as select electrodes 250) can each vertically extend through the capacitor stack structure 240 and be electrically connected with a corresponding one of the second conductive layers 259 but electrically isolated from the first conductive layers 269 and other second conductive layers 259 in the capacitor stack structure 240.

The first conductive layers 269, second conductive layers 259, conductive walls 260, and/or conductive vias 250 can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. In some implementations, the first conductive layers 269, second conductive layers 259, conductive walls 260, and/or conductive vias 250 can include multiple conductive layers, such as a W layer over a TiN layer. In some implementations, the second conductive layers 259 and the first conductive layers 269 can comprise a same conductive material. In some other implementations, the first conductive layers 269 and conductive walls 260 can comprise a first conductive material, and the second conductive layers 259 and conductive vias 250 can comprise a second conductive material different from the first conductive material.

In some implementations, conductive connection structures 256 can be each located between one of the conductive vias 250 and the corresponding one of the second conductive layers 259 to connect the one of the conductive vias 250 to the corresponding one of the second conductive layers 259. For example, as shown in FIG. 2, the conductive via 250-1 is electrically coupled with the corresponding conductive layer 259-1 through conductive connection structure 256-1, the conductive via 250-2 is electrically coupled with the corresponding conductive layer 259-2 through conductive connection structure 256-2, and the conductive via 250-3 is electrically coupled with the corresponding conductive layer 259-3 through conductive connection structure 256-3. In some implementations, the conductive connection structures 256 can comprise a metal silicide material. In some implementations, each conductive connection structure 256 has a ring structure laterally surrounding a corresponding one of the conductive vias 250.

In some implementations, a plurality of isolation structures 280 can be located between the conductive vias 250 and the second conductive layers 259 other than the corresponding conductive layers 259 that are connected to the conductive vias 250. As such, the conductive vias 250 can be isolated from the non-related second conductive layers 259. For example, the conductive via 250-1 is isolated from the second conductive layers 259 other than the corresponding conductive layer 259-1, and the conductive via 250-2 is isolated from the second conductive layers 259 other than the corresponding conductive layer 259-2, and the conductive via 250-3 is isolated from the second conductive layers 259 other than the corresponding conductive layer 259-3, as shown in FIG. 2. In some implementations, the isolation structures 280 can comprise any suitable insulating material, such as silicon oxide. In some implementations, each isolation structure 280 has a ring structure laterally surrounding a corresponding one of the conductive vias 250.

In some implementations, as shown in FIGS. 2 and 3, the capacitor stack structure 240 can further include a dielectric layer 270. The dielectric layer 270 can include horizontal portions between adjacent first conductive layers 269 and second conductive layers 259, first vertical portions between the conductive wall 260 and the second conductive layer 259, and second vertical portions between the conductive vias 250 and the first conductive layers 269. In some implementations, the dielectric layer comprises any suitable high-K material. In some implementations, the dielectric layer 270 is in contact with the side surfaces of the conductive wall 260 and the conductive vias 250, and horizontal surfaces of the first conductive layers 269 and second conductive layers 259.

As shown in FIG. 3, the disclosed memory device can further include a plurality of slit structures 380, each extending vertically through the capacitor stack structure 240 and laterally along a first direction (the x-direction) between adjacent rows of conductive vias 250. The conductive walls 260 can each extend laterally along a second direction (the y-direction) to cut off the slit structures 380.

In summary, the first conductive layers 269 and the connected conductive walls 260 together form the common first electrode (or upper electrode) of the capacitors of the capacitor stack structure 240, and the second conductive layers 259 and the connected conductive vias 250 together form the plurality of individual second electrodes (or lower electrodes) each coupled with a corresponding one of the array of transistors in the transistor layer 220 through a corresponding storage node contact (SNC) structure.

In some implementations, one or more peripheral circuits (not shown) can be coupled to the disclosed memory devices shown in FIGS. 2 and 3 through the bit lines, the word lines, the common electrode of the capacitors, the select electrode of the capacitors, and any other suitable metal wirings. It is noted that the one or more peripheral circuits can include any suitable circuits for facilitating the operations of disclosed memory devices by applying and sensing voltage signals and/or current signals through the word lines and the bit lines to and from each memory cell. The one or more peripheral circuits can include various types of peripheral circuits formed using CMOS technologies.

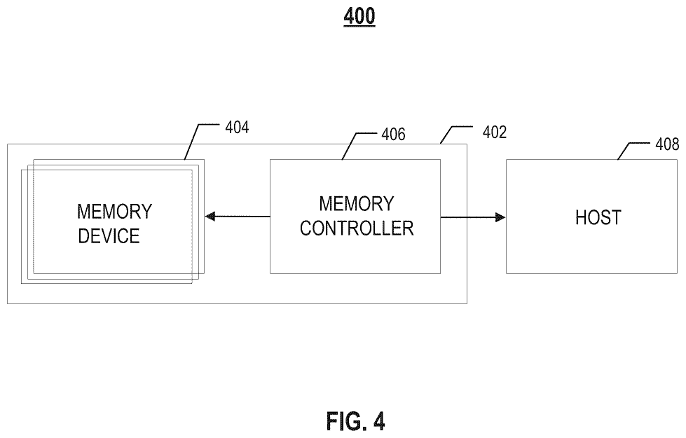

FIG. 4 illustrates a block diagram of a system 400 having a memory device, according to some implementations of the present disclosure. System 400 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 4, system 400 can include a host 408 and a memory system 402 having one or more memory devices 404 and a memory controller 406. Host 408 can be a processor of an electronic device, such as a central processing unit (CPU), or a system-on-chip (SoC), such as an application processor (AP). Host 408 can be configured to send or receive the data to or from memory devices 404. Memory device 404 can be any memory devices disclosed herein, such as memory devices shown in FIGS. 2 and 3.

Memory controller 406 is coupled to memory device 404 and host 408 and is configured to control memory device 404, according to some implementations. Memory controller 406 can manage the data stored in memory device 404 and communicate with host 408. Memory controller 406 can be configured to control operations of memory device 404, such as read, write, and refresh operations. Memory controller 406 can also be configured to manage various functions with respect to the data stored or to be stored in memory device 404 including, but not limited to refresh and timing control, command/request translation, buffer and schedule, and power management. In some implementations, memory controller 406 is further configured to determine the maximum memory capacity that the computer system can use, the number of memory banks, memory type and speed, memory particle data depth and data width, and other important parameters. Any other suitable functions may be performed by memory controller 406 as well. Memory controller 406 can communicate with an external device (e.g., host 408) according to a particular communication protocol. For example, memory controller 406 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

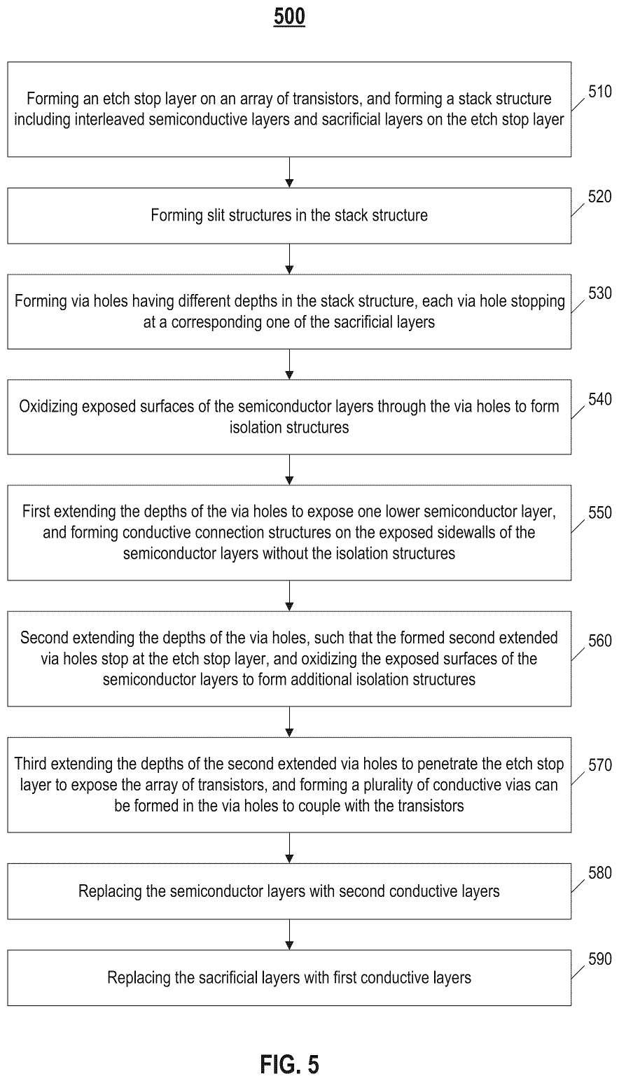

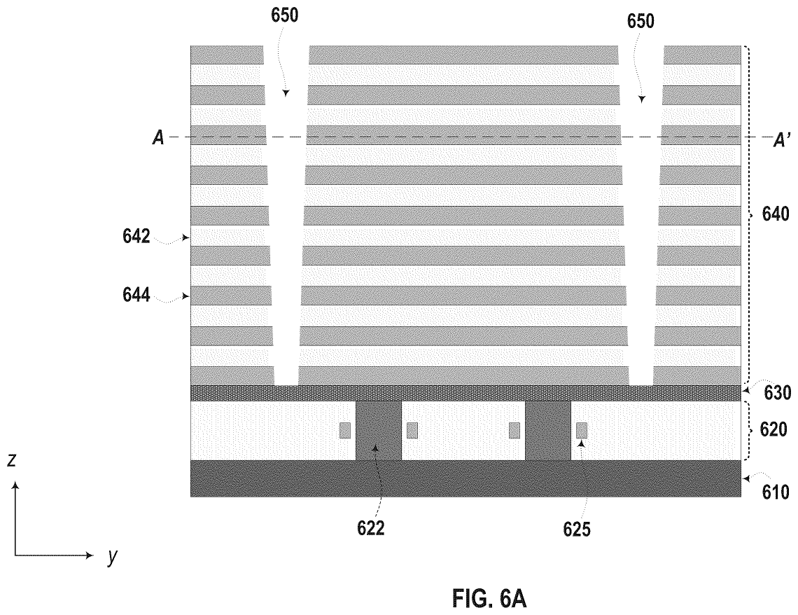

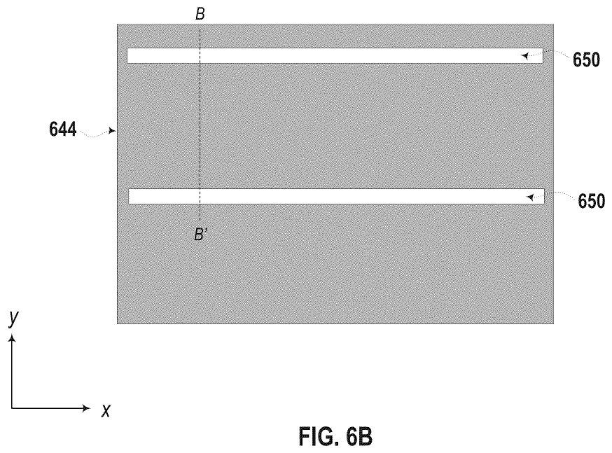

FIG. 5 illustrates a flowchart of a fabricating method 500 for forming a 3D memory device, according to some implementations of the present disclosure. FIGS. 6A-6B, 7A-7B, 8A-8B, 9A-9B, 10-11, 12A-12B, 13A-13B, 14, and 15A-15B illustrate schematic side cross-sectional views and/or planar cross-sectional views of a 3D memory device at certain fabricating stages of the method 500 shown in FIG. 5, according to various implementations of the present disclosure. It is understood that the operations shown in method 500 are not exhaustive and that other operations can be performed as well before, after, or between any of the illustrated operations. Further, some of the operations may be performed simultaneously, or in a different order than shown in FIG. 5.

As shown in FIG. 5, method 500 can start at operation 510, in which a stack structure can be formed on an array of transistors. The stack structure can comprise semiconductor layers and sacrificial layers alternately stacked along a vertical direction. FIG. 6A illustrates a schematic side cross-sectional view of the 3D memory device after operation 510 of method 500. FIG. 6B illustrates a schematic planar cross-sectional view of the 3D memory device after operation 510 of method 500. It is noted that, FIG. 6A illustrates the schematic side cross-sectional view of the 3D memory device shown in FIG. 6B along the B-B′ line in the y-z plane, and FIG. 6B illustrates the schematic planar cross-sectional view of the 3D memory device shown in FIG. 6A along the A-A′ line in the x-y plane.

In some implementations as shown in FIG. 6A, a transistor layer can be formed on a substrate 610. Substrate 610 can be a semiconductor substrate, which can include silicon (e.g., single crystalline silicon, c-Si), silicon germanium (SiGe), gallium arsenide (GaAs), germanium (Ge), silicon-on-insulator (SOI), or any other suitable materials. In some other implementations, substrate 610 can be a carrier substrate, which can include any suitable semiconductor materials, or an electrically non-conductive material, such as a glass, a plastic, or a sapphire wafer.

In some implementations as shown in FIG. 6A, the formed transistor layer 620 can include an array of vertical transistors. Specifically, forming the transistor layer 220 can include forming an array of channel structures 622 each extending along a vertical direction (the z-direction) on the substrate 610. The array of channel structures 622 can be formed by any suitable processes. For example, a deposition process (e.g., chemical vapor deposition (CVD), physical vapor deposition (PVD), atomic layer deposition (ALD), etc.) can be performed to form a semiconductor layer on substrate 610. A followed lithography process can be applied to pattern the semiconductor layer using an etch mask (e.g., a photoresist mask and/or a hard mask), and one or more dry etching and/or wet etching processes, such as RIE, are performed on the semiconductor layer to etch portions of the semiconductor layer to form the array of channel structures 622.

In some implementations, a material of channel structures 622 can include any suitable semiconductor material. For example, a material of channel structures 622 can be polysilicon. As another example, a material of channel structures 622 can be a metal oxide semiconductor material, such as IGZO. It is understood that cross-section of each channel structure 622 may have any suitable shape, such as a square shape, a rectangular shape (or a trapezoidal shape), a circular shape, a partial circular shape, an oval shape, a partial oval shape, or any other suitable shapes.

In some implementations, forming transistor layer 620 can further include forming a gate structure layer 625 along a lateral direction. Gate structure layer 625 can be formed to include a plurality of gate structures each located at one or more sides of the corresponding channel structure 622. As such, the formed array of vertical transistors can be gate-all-around (GAA) type vertical transistors, single metal gate (SMG) type vertical transistors, double metal gate (DMG) type vertical transistors, or triple metal gate (TMG) type vertical transistors, etc. Although not shown in FIG. 6A, each gate structure can include a gate electrode and a gate dielectric. The gate electrode can include any suitable conductive materials, such as polysilicon, metals (e.g., W, Cu, Al, etc.), metal compounds (e.g., TiN, TaN, etc.), or silicides. For example, the gate electrode may include doped polysilicon, i.e., a gate poly. In some other implementations, the gate electrode can include multiple conductive layers, such as a W layer over a TiN layer. The gate dielectric can include any suitable dielectric materials, such as silicon oxide, silicon nitride, silicon oxynitride, or high-k dielectrics. In some implementations, the gate structures of a row of the vertical transistors along a first lateral direction can be formed to connect with each other to form a word line extending along the first lateral direction (the x-direction).

In some implementations, although not shown in FIG. 6A, forming the transistor layer 620 can further include forming a plurality of storage node contact (SNC) structures (not shown), each in contact with an end (e.g., upper end) of a corresponding one of the array of the channel structures 622. The SNC structure can include any suitable conductive materials, such as polysilicon, metals (e.g., W, Cu, Al, etc.), metal compounds (e.g., TiN, TaN, etc.), silicides, and/or combinations thereof. Further, forming the transistor layer 620 can further include forming a plurality of bit lines (not shown), each extending in the second lateral direction (the y-direction) and being connected to the ends (e.g., lower ends) of a corresponding column of vertical transistors along the second lateral direction (the y-direction). For example, substrate 610 can be thinned, and a conductive layer can be formed and patterned to form the bit lines. The bit lines can include any suitable conductive materials, such as polysilicon, metals (e.g., W, Cu, Al, etc.), metal compounds (e.g., TiN, TaN, etc.), or silicides. For example, the bit lines can include multiple conductive layers, such as a W layer over a TiN layer.

As shown in FIG. 6A, an etch stop layer 630 can be formed on the transistor layer 620, and a stack structure 640 can be formed on the etch stop layer 630. In some implementations, the etch stop layer 630 can be formed by a thin film deposition process, such as CVD, PVD, ALD, etc. The etch stop layer 630 can include any suitable dielectric materials, such as silicon nitride, silicon oxynitride, or high-k dielectrics. The stack structure 640 can comprise semiconductor layers 644 and sacrificial layers 642 alternately stacked along the vertical direction (the z-direction). In some implementations, the interleaved semiconductor layers 644 and sacrificial layers 642 can be formed by multiple thin film deposition processes, such as CVD, PVD, ALD, etc. Semiconductor layers 644 can include any suitable semiconductor materials, such as Si (e.g., c-Si, poly-Si), SiGe, GaAs, Ge, etc. The sacrificial layers 642 can be an insulating layer including any suitable insulating material having an etching ratio different from that of the material of the semiconductor layers 644 during one or more selective etching processes. In some implementations, the sacrificial layers 642 includes silicon nitride.

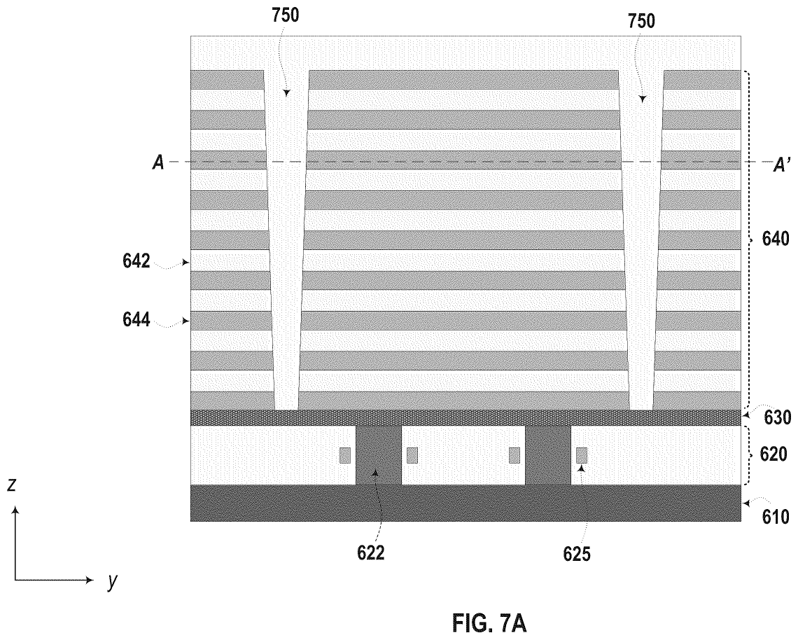

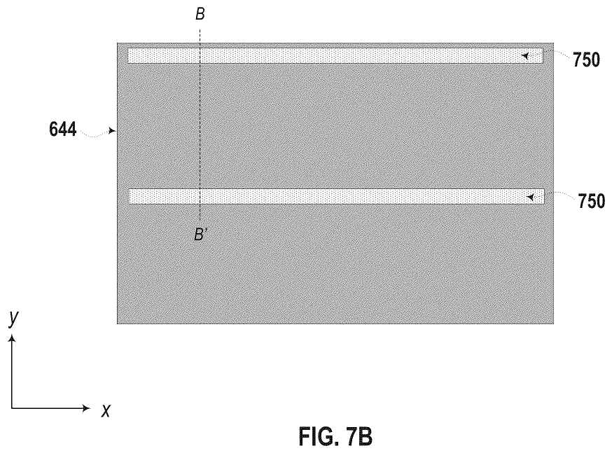

Referring back to FIG. 5, method 500 can process to operation 520, in which slit structures can be formed in the stack structure. Each slit structure can extend vertically through the stack structure and laterally along a first direction. FIG. 7A illustrates a schematic side cross-sectional view of the 3D memory device after operation 520 of method 500. FIG. 7B illustrates a schematic planar cross-sectional view of the 3D memory device after operation 520 of method 500. It is noted that, FIG. 7A illustrates the schematic side cross-sectional view of the 3D memory device shown in FIG. 7B along the B-B′ line in the y-z plane, and FIG. 7B illustrates the schematic planar cross-sectional view of the 3D memory device shown in FIG. 7A along the A-A′ line in the x-y plane.

As shown in FIGS. 6A and 6B, the stack structure 640 can be patterned to form a plurality of first slits 650, parallelly arranged in the second lateral direction (the y-direction), each extending along the first lateral direction (the x-direction). The plurality of first slits 650 can vertically extend through the stack structure 640 and stop at the etch stop layer 630, and laterally extending along the first lateral direction (the x-direction). The plurality of first slits 650 can be formed by any suitable etching process (e.g., photo etching, dry etching, wet etching, cleaning, etc.).

As shown in FIGS. 7A and 7B, a plurality of slit structures 750 can be formed in the first slits 650. The slit structures 750 can include any suitable dielectric materials, such as silicon oxide, silicon oxynitride, or high-k dielectrics. In some implementations, the slit structures 750 can be formed by any suitable deposition process, such as CVD, PVD, ALD, etc., and a followed chemical mechanical polishing (CMP) process. The formed slit structures 750 can laterally extend parallel along the first lateral direction (the x-direction).

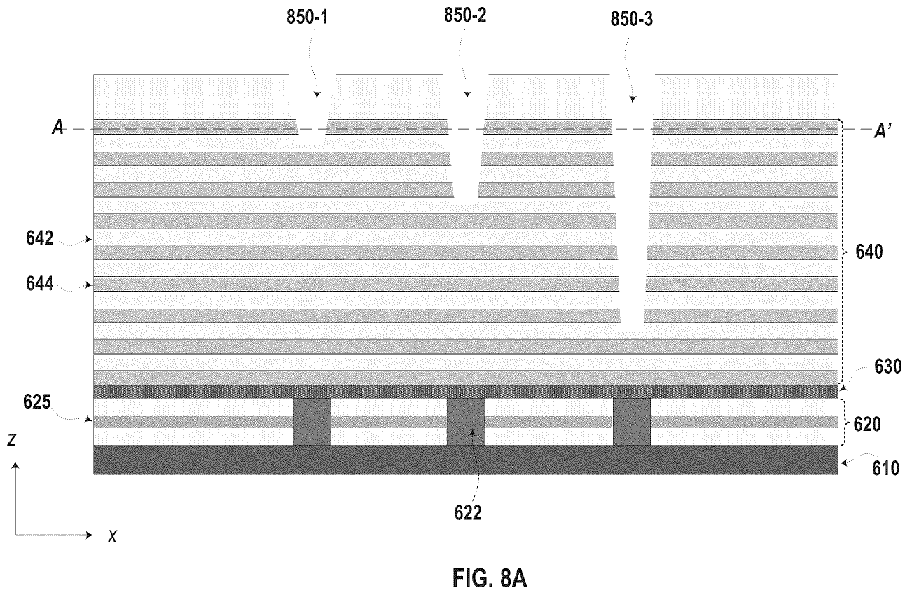

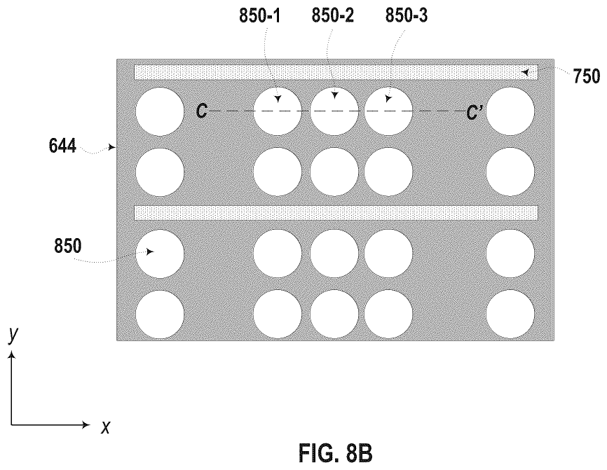

Referring back to FIG. 5, method 500 can proceed to operation 530, in which a plurality of via holes having different depths can be formed in the stack structure. Each via hole can stop at a corresponding one of the sacrificial layers. FIG. 8A illustrates a schematic side cross-sectional view of the 3D memory device after operation 530 of method 500. FIG. 8B illustrates a schematic planar cross-sectional view of the 3D memory device after operation 530 of method 500. It is noted that, FIG. 8A illustrates the schematic side cross-sectional view of the 3D memory device shown in FIG. 8B along the C-C′ line in the x-z plane, and FIG. 8B illustrates the schematic planar cross-sectional view of the 3D memory device shown in FIG. 8A along the A-A′ line in the x-y plane.

As shown in FIGS. 8A and 8B, an array of via holes 850 can be formed in the stack structure 640. Each of the via holes 850 can stop at a corresponding one of the sacrificial layers 642. As such, each individual via hole (e.g., via hole 850-1, via hole 850-2, via hole 850-3, etc.) can have a different depth in the vertical direction (the z-direction). In the planar view as shown in FIG. 8B, the array of via holes 850 can be arranged in rows extending in parallel along the first lateral direction (the x-direction) and in columns extending parallel along the second lateral direction (the y-direction). In some implementations, one or more rows of via holes 850 can be located between adjacent slit structures 750. In some implementations, the array of via holes 850 can be formed by any suitable etching process.

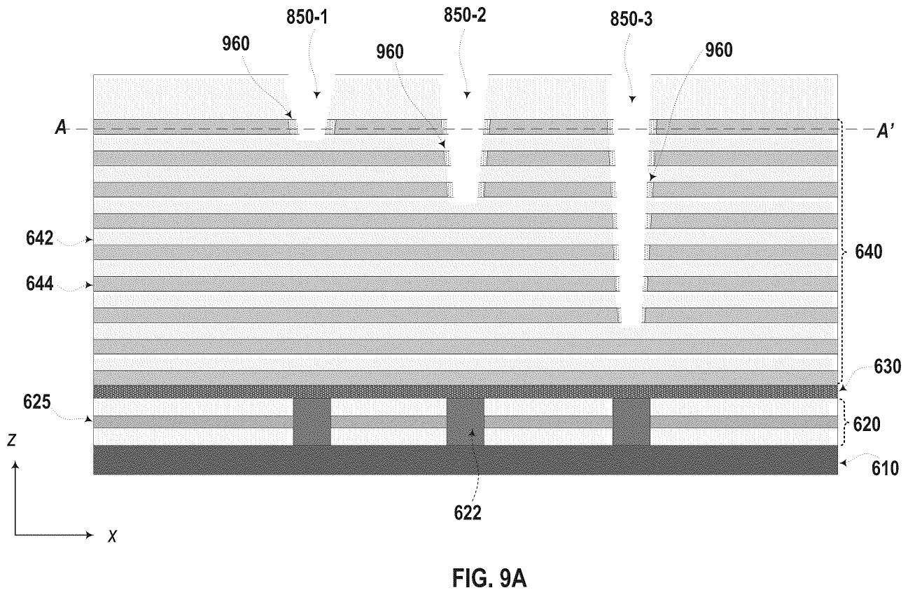

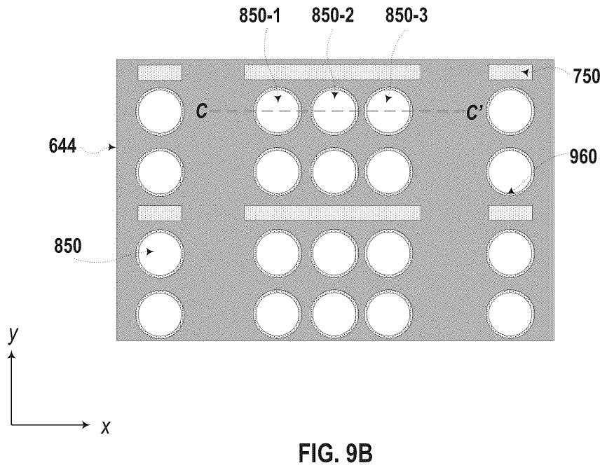

Referring back to FIG. 5, method 500 can proceed to operation 540, in which the exposed surfaces of the semiconductor layers through the via holes can be oxidized to form isolation structures. FIG. 9A illustrates a schematic side cross-sectional view of the 3D memory device after operation 540 of method 500. FIG. 9B illustrates a schematic planar cross-sectional view of the 3D memory device after operation 540 of method 500. It is noted that, FIG. 9A illustrates the schematic side cross-sectional view of the 3D memory device shown in FIG. 9B along the C-C′ line in the x-z plane, and FIG. 9B illustrates the schematic planar cross-sectional view of the 3D memory device shown in FIG. 9A along the A-A′ line in the x-y plane.

As shown in FIGS. 9A and 9B, the exposed surfaces of the sidewall of the semiconductor layers 644 by the via holes 850 can be oxidized to form isolation structures 960. As shown in FIG. 9B, each of the isolation structures 960 has a ring-shaped structure laterally surrounding a corresponding one of the via holes 850. Since the via holes 850 have different depths in the vertical direction (the z-direction) and expose different numbers of semiconductor layers 644 in the stack structure 640, the number of formed isolation structures 960 in different via holes 850 correspond to the numbers of the semiconductor layers 644 penetrated by each of the via holes 850, respectively. For example, as shown in FIG. 9A, via hole 850-1, via hole 850-2, via hole 850-3 each exposes different numbers of semiconductor layers 644 in the stack structure 640, and thus the numbers of the formed isolation structures 960 in via hole 850-1, via hole 850-2, via hole 850-3 are also different.

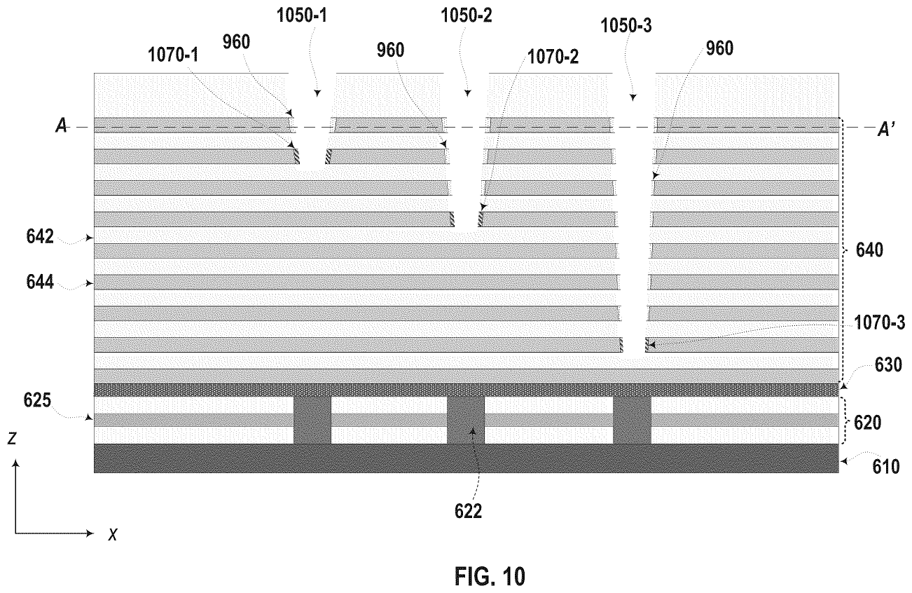

Referring back to FIG. 5, method 500 can proceed to operation 550, in which the via holes can be further etched to first extend the depths of the via holes, such that each first extended via hole exposing one lower semiconductor layer without the isolation structures, and conductive connection structures can be formed on the exposed sidewalls of the semiconductor layers without the isolation structures through the first extended via holes. FIG. 10 illustrates a schematic side cross-sectional view of the 3D memory device after operation 550 of method 500.

As shown in FIG. 10, the via holes 850 can be further etched to first extend the depths, such that each first extended via hole 1050 (e.g., first extended via holes 1050-1, 1050-2, 1050-3) can expose one lower semiconductor layer 644 without the isolation structures 960. The conductive connection structures 1070 (e.g., conductive connection structures 1070-1, 1070-2, 1070-3) can be formed on the exposed sidewalls of the semiconductor layers 644 without the isolation structures 960 through the first extended via holes 1050, respectively. In some implementations, the conductive connection structures 1070 can comprise a metal silicide material, such as titanium silicide, nickel silicide, cobalt silicide, etc. The conductive connection structures 1070 can be formed by performing a metal ion implantation and/or thermal diffusion to transform the exposed surfaces of the exposed sidewalls of the semiconductor layers 644 without the isolation structures 960 through the first extended via holes 1050. In some implementations, each of the conductive connection structures 1070 can have a ring structure laterally surrounding a corresponding one of the first extended via holes 1050.

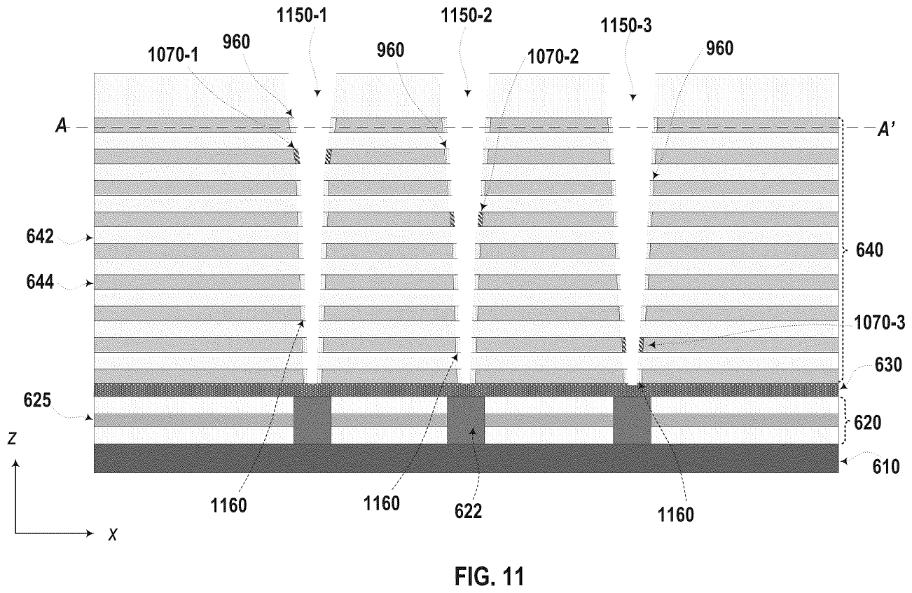

Referring back to FIG. 5, method 500 can proceed to operation 560, in which the first extended via holes can be further etched to second extend the depths of the first extended via holes, such that the formed second extended via holes stops at the etch stop layer, and the exposed surfaces of the semiconductor layers through the second extended via holes can be oxidized to form additional isolation structures. FIG. 11 illustrates a schematic side cross-sectional view of the 3D memory device after operation 560 of method 500.

As shown in FIG. 11, the first extended via holes 1050 can be further etched to second extend the depths, such that each second extended via hole 1150 (e.g., second extended via holes 1150-1, 1150-2, 1150-3) can expose one lower semiconductor layer 644 without the isolation structures 960. The second extended via holes 1150 can stop at the etch stop layer 630, thus having the same depth. The second extended via holes 1150 can expose the sidewalls of the semiconductor layers 644 below the conductive connection structures 1070 in each of the second extended via holes 1050, respectively. The exposed surfaces of the sidewall of semiconductor layers 644 below the conductive connection structures 1070 in the second extended via holes 1050 can be oxidized to form additional isolation structures 1160. Each of the additional isolation structures 1160 has a ring-shaped structure laterally surrounding a corresponding one of the second extended via holes 1150.

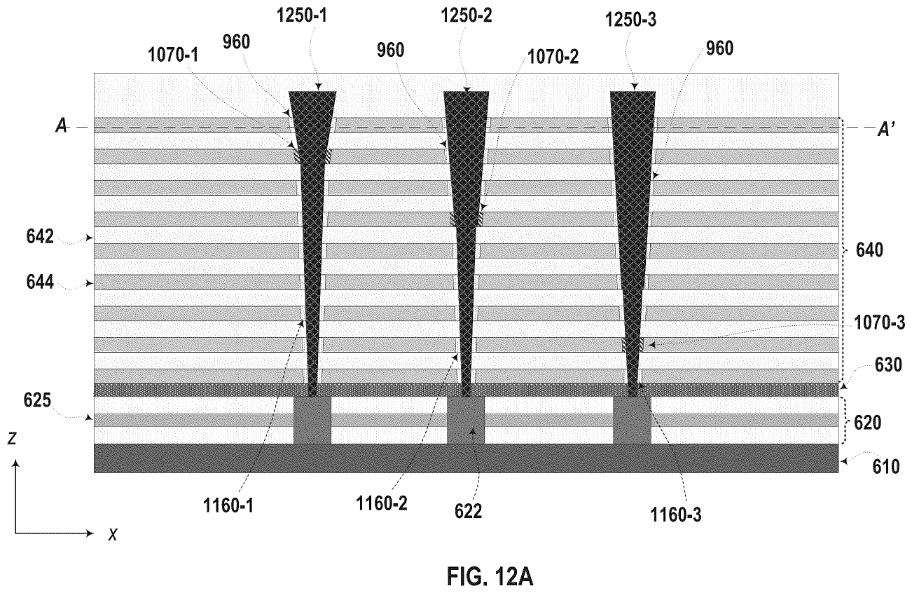

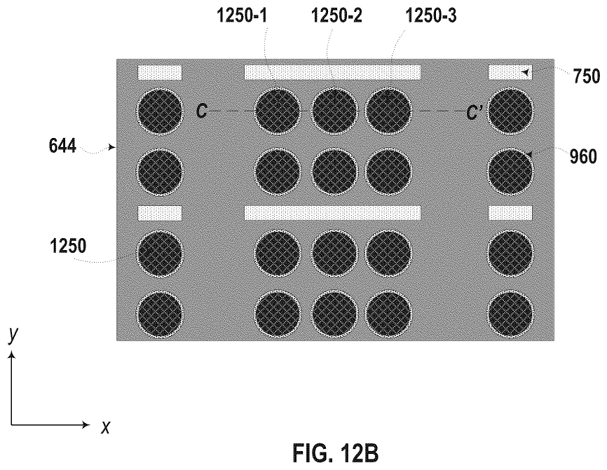

Referring back to FIG. 5, method 500 can proceed to operation 570, in which the second extended via holes can be further etched to third extend the depths of the second extended via holes, such that the formed third extended via holes extend through the etch stop layer to expose the transistor layer, and a plurality of conductive vias can be formed in the third extended via holes to couple with the transistor layer. FIG. 12A illustrates a schematic side cross-sectional view of the 3D memory device after operation 570 of method 500. FIG. 12B illustrates a schematic planar cross-sectional view of the 3D memory device after operation 570 of method 500. It is noted that, FIG. 12A illustrates the schematic side cross-sectional view of the 3D memory device shown in FIG. 12B along the C-C′ line in the x-z plane, and FIG. 12B illustrates the schematic planar cross-sectional view of the 3D memory device shown in FIG. 12A along the A-A′ line in the x-y plane.

As shown in FIGS. 12A and 12B, the second extended via holes 1150 can be further etched to third extend the depths, such that the formed third extended via holes extend through the etch stop layer 630 to expose the transistor layer 620. In some implementations, any suitable etching process, such as a punch operation, can be performed to remove portions of the etch stop layer 630 to expose the SNC structures of the array of vertical transistors in the transistor layer 620. A deposition process, such as CVD, PVD, ALD, etc., can be then performed to fill the third extended via holes to form the plurality of conductive vias 1250 (e.g., conductive vias 1250-1, 1250-2, 1250-3) in the third extended via holes. Each conductive via 1250 can be vertically extended through stack structure 640 and the etch stop layer 630 and in contact with the SNC structures of the array of vertical transistors in the transistor layer 620.

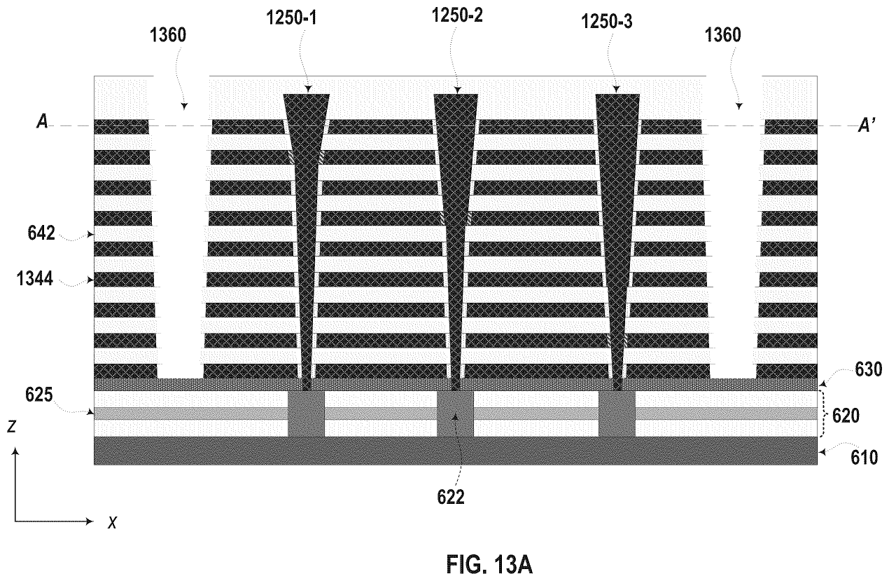

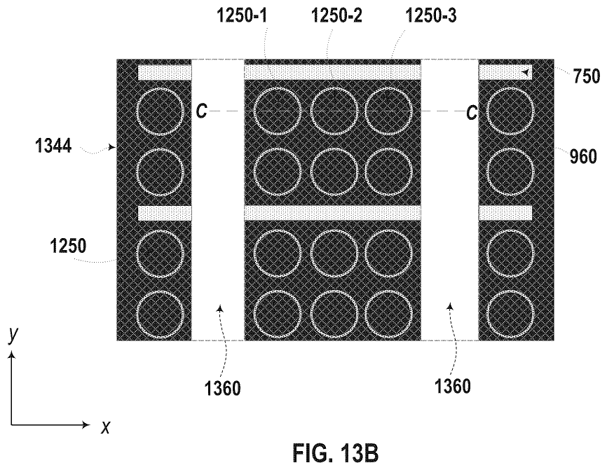

Referring back to FIG. 5, method 500 can proceed to operation 580, in which the semiconductor layers can be replaced with a plurality of second conductive layers. In some implementations, replacing the semiconductor layers with the second conductive layers includes forming one or more slits vertically extending through the stack structure and stopping at the insulating layer, removing the semiconductor layers through the slit to form the first horizontal trenches, and forming the second conductive layers in the first horizontal trenches. FIG. 13A illustrates a schematic side cross-sectional view of the 3D memory device after operation 580 of method 500. FIG. 13B illustrates a schematic planar cross-sectional view of the 3D memory device after operation 580 of method 500. It is noted that, FIG. 13A illustrates the schematic side cross-sectional view of the 3D memory device shown in FIG. 13B along the C-C′ line in the x-z plane, and FIG. 13B illustrates the schematic planar cross-sectional view of the 3D memory device shown in FIG. 13A along the A-A′ line in the x-y plane.

As shown in FIGS. 13A and 13B, the stack structure 640 can be patterned to form a plurality of second slits 1360, parallelly arranged in the first lateral direction (the x-direction), each extending along the second lateral direction (the y-direction). The plurality of second slits 1360 can vertically extend through the stack structure 640 and stop at the etch stop layer 630, and laterally extend along the second lateral direction (the y-direction). The plurality of second slits 1360 can be formed by any suitable etching process (e.g., photo etching, dry etching, wet etching, cleaning, etc.). The semiconductor layers 644 of the stack structure 640 can be removed through the second slits 1360 to form the first horizontal trenches (not shown), and the second conductive layers 1344 can be formed in the first horizontal trenches by any suitable deposition process, such as CVD, PVD, ALD, etc. In some implementations, the second conductive layers 1344 can include any suitable conductive materials, such as metals (e.g., W, Cu, Al, etc.) or metal compounds (e.g., TiN, TaN, etc.).

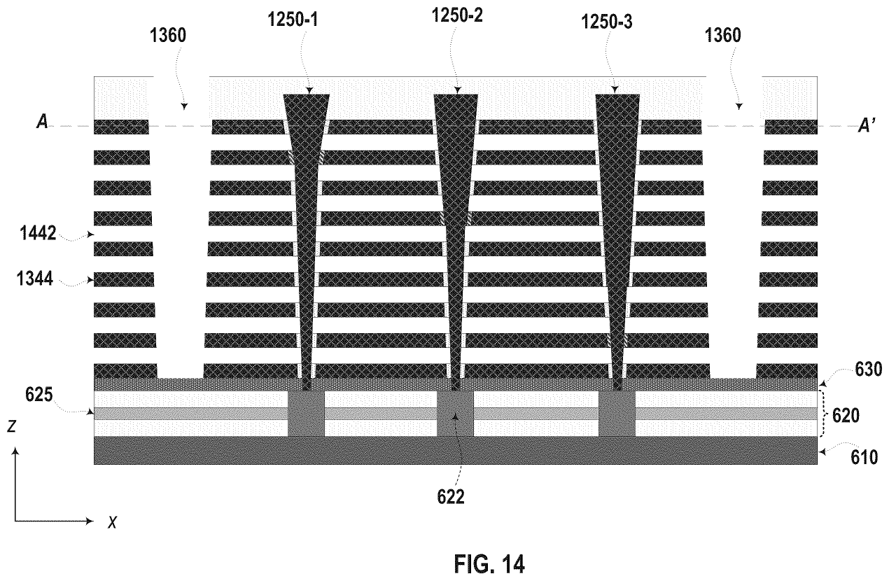

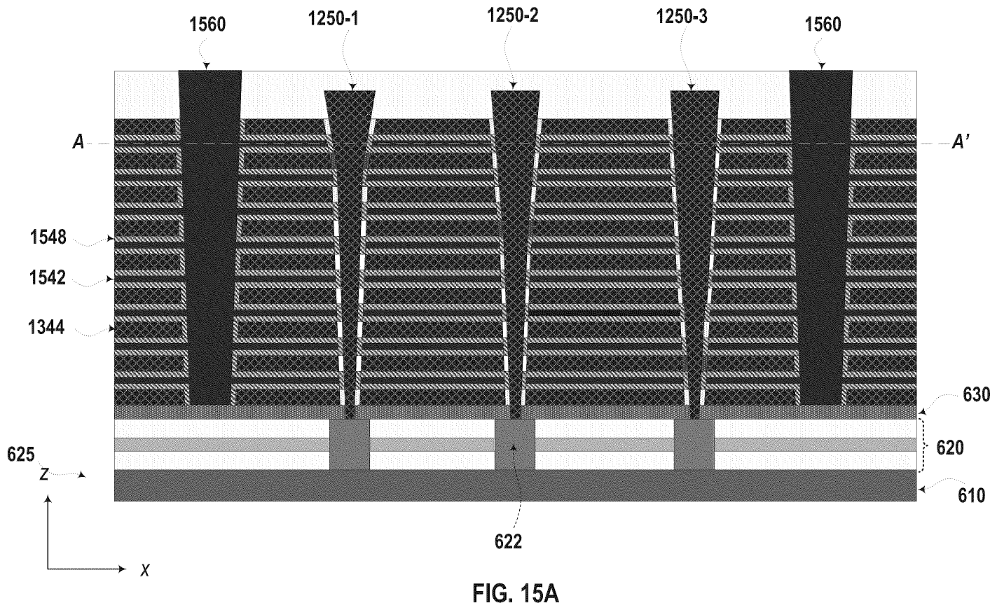

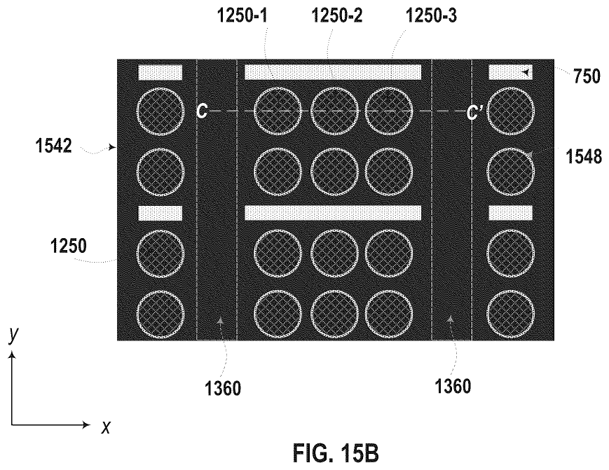

Referring back to FIG. 5, method 500 can proceed to operation 590, in which the sacrificial layers can be replaced with a plurality of first conductive layers, and one or more conductive walls can be formed. In some implementations, replacing the sacrificial layers with the first conductive layers includes removing portions of the second conductive layers exposed by the second slits, removing the sacrificial layers through the second slit to form second horizontal trenches, forming a dielectric layer in the second horizontal trenches and on sidewalls of the slit to cover exposed surfaces of the second conductive layers, and forming the first conductive layers in the second horizontal trenches. The one or more conductive walls can be formed in the second slits. FIG. 14 illustrates a schematic side cross-sectional view of the 3D memory device during operation 590 of method 500. FIG. 15A illustrates a schematic side cross-sectional view of the 3D memory device after operation 590 of method 500. FIG. 15B illustrates a schematic planar cross-sectional view of the 3D memory device after operation 590 of method 500. It is noted that, FIG. 15A illustrates the schematic side cross-sectional view of the 3D memory device shown in FIG. 15B along the C-C′ line in the x-z plane, and FIG. 15B illustrates the schematic planar cross-sectional view of the 3D memory device shown in FIG. 15A along the A-A′ line in the x-y plane.

As shown in FIG. 14, the portions of the deposited conductive material in the second slits 1360 and portions of the second conductive layers 1344 adjacent to the second slits 1360 can be firstly removed by any suitable etching/cleaning process, and the sacrificial layers 642 can be removed through the second slit 1360 to form a plurality of second horizontal trenches 1442. The sacrificial layers 642 can be removed by any suitable selective etching process. The formed plurality of second horizontal trenches 1442 can expose the top and bottom surfaces of the second conductive layers 1344, and portions of the sidewalls of the plurality of conductive vias 1250.

As shown in FIGS. 15A and 15B, a dielectric layer 1548 can be formed in the second horizontal trenches 1442 and on the sidewalls of the second slits 1360 to cover the exposed surfaces of the second conductive layers 1344 and the exposed sidewalls of the plurality of conductive vias 1250. In some implementations, the dielectric layer 1548 can include any suitable high-k dielectric material including, but not limited to, Al₂O₃, HfO₂, Ta₂O₅, ZrO₂, TiO₂, or any combination thereof, and can be formed by any suitable thin film deposition processes (e.g., CVD, PVD, ALD, etc.) In some implementations, a conductive material can then be deposited in the second horizontal trenches 1442 and the second slits 1360 to form the first conductive layers 1542 and the conductive walls 1560, respectively. The first conductive layers 1542 and the conducive walls 1560 can be formed by any suitable deposition process, such as CVD, PVD, ALD, etc., and can include any suitable conductive materials, such as metals (e.g., W, Cu, Al, etc.) or metal compounds (e.g., TiN, TaN, etc.).

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described implementations, but should be defined only in accordance with the following claims and their equivalents.

What is claimed is:

1. A semiconductor device, comprising:
a stack structure comprising first conductive layers and second conductive layers alternately stacked along a vertical direction;
a conductive wall vertically extending through the stack structure and in contact with the first conductive layers but isolated from the second conductive layers; and
conductive vias each vertically extending through the stack structure and electrically connected with a corresponding one of the second conductive layers but electrically isolated from the first conductive layers and other second conductive layers in the stack structure.

2. The semiconductor device of claim 1, further comprising:
isolation structures between the conductive vias and the other second conductive layers to isolate the conductive vias and the other second conductive layers; and
conductive connection structures each between one of the conductive vias and the corresponding one of the second conductive layers to connect the one of the conductive vias to the corresponding one of the second conductive layers.

3. The semiconductor device of claim 2, wherein:
the isolation structures comprise silicon oxide; and
the conductive connection structures comprise a metal silicide material.

4. The semiconductor device of claim 2, wherein:
each of the isolation structures and the conductive connection structures has a ring structure laterally surrounding a corresponding one of the conductive vias.

5. The semiconductor device of claim 1, wherein:
the first conductive layers and the conductive wall comprise a first conductive material; and
the second conductive layers and the conductive vias comprise a second conductive material different from the first conductive material.

6. The semiconductor device of claim 1, further comprising:
a dielectric layer comprising:
horizontal portions between adjacent first conductive layers and second conductive layers;
first vertical portions between the conductive wall and the second conductive layers; and
second vertical portions between the conductive vias and the first conductive layers.

7. The semiconductor device of claim 6, wherein:
the dielectric layer is in contact with side surfaces of the conductive wall and the conductive vias, and horizontal surfaces of the first conductive layers and second conductive layers.

8. The semiconductor device of claim 1, further comprising:
an array of transistors coupled with the conductive vias, respectively,
wherein the transistors are vertical gate transistors each comprising a channel structure extending along a vertical direction and a gate structure at a lateral side of the channel structure.

9. The semiconductor device of claim 8, further comprising:
an insulating layer between the stack structure and the array of transistors,
wherein each conductive via extends through the insulating layer to couple with a corresponding one of the array of transistors.

10. The semiconductor device of claim 1, wherein:
a first thickness of the first conductive layers is different from a second thickness of the second conductive layers.

11. The semiconductor device of claim 1, further comprising:
a slit structure extending vertically through the stack structure and laterally along a first direction between adjacent rows of conductive vias,
wherein the conductive wall extends laterally along a second direction to cut off the slit structure.

12. A memory device, comprising:
a capacitor stack structure comprising:
first electrode plates and second electrode plates alternatively stacked along a vertical direction,
a common electrode vertically extending through the capacitor stack structure and in contact with the first electrode plates, and
select electrodes each extending through the capacitor stack structure and in contact with a corresponding one of the second electrode plates; and
an array of transistors each coupled with a corresponding one of the select electrodes.

13. The memory device of claim 12, further comprising:
a high-K layer between adjacent first electrode plates and second electrode plates, between the first electrode plates and the common electrode, and between the second electrode plates and the select electrodes.

14. The memory device of claim 12, further comprising:
conductive connection structures each between one of the select electrodes and the corresponding one of the second electrode plates to electrically connect the one of the select electrodes and the corresponding one of the second electrode plates; and
isolation structures between the one of the select electrodes and other second electrode plates different from the corresponding one of the second electrode plates.

15. The memory device of claim 14, wherein:
the isolation structures comprise silicon oxide; and
the conductive connection structures comprise a metal silicide material.

16. The memory device of claim 14, wherein:
each of the isolation structures and the conductive connection structures has a ring structure laterally surrounding a corresponding one of the select electrodes.

17. The memory device of claim 12, wherein:
the first electrode plates and the common electrode comprise a first conductive material; and
the second electrode plates and the select electrodes comprise a second conductive material different from the first conductive material.

18. The memory device of claim 12, further comprising:
an insulating layer between the capacitor stack structure and the array of transistors,
wherein the select electrodes extend through the insulating layer.

19. The memory device of claim 12, wherein:
the transistors are two-dimensional transistors or vertical gate transistors.

20. The memory device of claim 12, further comprising:
a slit structure extending vertically through the capacitor stack structure and laterally along a first direction between adjacent rows of select electrodes,
wherein the common electrode extends laterally along a second direction to cut off the slit structure.
